(19) United States
(12) Patent Application Publication
(10) Pub. No.: US 2006/0098492 A1
(43) Pub. Date: May 11, 2006

(54) Erase-verifying method of NAND type flash memory device and NAND type flash memory device thereof

(75) Inventor: Hee Youl Lee, Icheon-si (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/126,321

(22) Filed: May 11, 2005

(30) Foreign Application Priority Data
Nov. 11, 2004 (KR) 10-2004-92095

(51) Int. Cl. G11C 16/04

(52) U.S. Cl. 365/185.29

(57) ABSTRACT

An erase-verifying method of a NAND type flash memory device and NAND type flash memory device thereof, wherein an erase-verifying operation is performed by applying a positive voltage as a source voltage. Considering a variation width of a threshold voltage of an erase cell, which shifts due to various factors, a negative threshold voltage of an erase cell can be stably verified. Through this, even when the threshold voltage of the erase cell shifts due to disturbance upon subsequent program operation, the number of cells failed can be reduced.

### BACKGROUND

1. Field of the Invention

The present invention relates to an erase-verifying method of a NAND type flash memory device and NAND type flash memory device thereof, and more specifically, to an erase-verifying method of a NAND type flash memory device and NAND type flash memory device thereof, wherein a threshold voltage of an erase cell is increased with no shift in the amount of electrons charged into a floating gate, whereby the threshold voltage of the erase cell is verified in a stable manner.

2. Discussion of Related Art

Recently, there has been an increasing demand for flash memory devices in which an electrical program and an erase are allowed, and a refresh function of rewriting data at a given cycle is not required. Further, in order to develop large-capacity memory devices capable of storing lots of data, research into higher integration technology of memory devices has been actively pursued. In this case, the term “program” refers to an operation for writing data into memory cells, and the term “erase” refers to an operation for erasing data written into the memory cells.

For higher integration of memory devices, NAND type flash memory devices have been developed in which a plurality of memory cells are connected in a serial manner (i.e., a structure wherein a drain or source is shared among neighboring cells) to form a single string. The NAND type flash memory devices are memory devices for reading information in a sequential manner unlike NOR type flash memory devices. Program and erase of this NAND type flash memory device are performed by controlling the threshold voltage Vt of the memory cell, while injecting or discharging electrons into or from the floating gate by way of F—N tunneling.

In the NAND type flash memory device, securing reliability of the memory cell is a crucial problem. Particularly, data retention of the memory cell comes into the limelight as an important problem. As described above, however, in the NAND type flash memory device, the program operation and the erase operation are carried out by way of F—N tunneling. During such a repetitive F—N tunneling process, electrons are trapped within a tunnel oxide film of the memory cell, which causes the threshold voltage Vt of the memory cell to shift. Therefore, there occurs a case where data originally stored in a memory cell is erroneously recognized in the read operation of the data. That is, there is a problem in that the reliability of the memory cell is lowered.

Shift in the threshold voltage of the memory cell is caused by electrons that are trapped within the tunnel oxide film by means of repetitive F—N tunneling by cycling. At this time, the term “cycling” refers to a process for repetitively performing the program operation and the erase operation. As a solution for preventing such shift in the threshold voltage of a memory cell, there has been proposed a method in which an erase voltage is sufficiently lowered below a verify voltage by controlling a bias condition (i.e., a bias voltage) upon program operation and the erase operation. This method, however, still has a problem in that a threshold voltage increases as degree as a bias voltage increases, and the threshold voltage shifts accordingly. As an alternative method for preventing shift in the threshold voltage of the memory cell, there has been proposed a method in which a thickness of a tunnel oxide film is reduced, and the amount of electrons trapped upon F—N tunneling is thus reduced. The method of reducing the thickness of the tunnel oxide film, however, is limited due to a fundamental data retention characteristic problem or a read disturbance problem.

Meanwhile, monitoring shift in a threshold voltage of a memory cell is also very important as well as reducing shift in the threshold voltage of the memory cell. As shown in FIG. 9, generally, in a program state, the threshold voltage of the memory cell is positive, and in an erase state, the threshold voltage of the memory cell is negative. It is, however, almost impossible to monitor the threshold voltage of the memory cell, which is currently negative. This is because in a NAND type flash memory device, the negative voltage is not used as a word line Vwl. The lowest word line bias voltage Vwl, which can now be used in a NAND type flash memory device, is 0V.

Accordingly, upon erase-verifying operation after erase operation, if the threshold voltage of a memory cell is lower than 0V, the memory cell is determined as an erased cell on which erase is stably performed (hereinafter, referred to as “erase cell”). As such, since all cells having a threshold voltage lower than 0V upon erase-verifying operation are all determined as erase cells, not only a memory cell having a threshold voltage of −2V, but also a memory cell having a threshold voltage of −0.1V are determined as the erase cell, as shown in FIG. 10.

In this case, there is no significant problem in the memory cell having the threshold voltage of −2V, but there will be a significant problem in the memory cell having the threshold voltage of −0.1V. This is because the threshold voltage of the erase cell is shifted by the effects of a program operation and an erase operation of neighboring cells, or degradation of a memory cell depending upon repetitive program operations and erase operations of a corresponding cell, as described above. Accordingly, in case of an erase cell having a threshold voltage close to 0V, the threshold voltage is easily shifted to 0V or more. That is, although a cell has been determined to be an erase cell by the erase-verifying operation, the threshold voltage is increased to 0V or more due to a variety of factors. Accordingly, there occurs a problem in that device characteristics are degraded.

### SUMMARY OF THE INVENTION

Accordingly, the present invention has been made in view of the above problems, and it is an object of the present invention to provide an erase-verifying method of a NAND type flash memory device and NAND type flash memory device thereof, wherein a threshold voltage of a cell is increased only with an operation mode without shift (i.e., shift in a basic threshold voltage of an erase cell) in the amount of electrons charged into a floating gate, whereby the threshold voltage of the erase cell is verified in a stable manner.

To achieve the above object, according to an aspect of the present invention, there is provided an erase-verifying method of a NAND type flash memory device including a plurality of memory cells, which are serially connected to each other and selected by a word line, a first transistor connected to a first memory cell of the plurality of the memory cells, for connecting a bit line and the first memory cell, and a second transistor connected to a source terminal of a last memory cell of the plurality of the memory cells, wherein an erase-verifying operation is performed by applying 0V to the word line and a positive voltage to the bit line and the source terminal of the last memory cell.

According to another aspect of the present invention, there is provided a NAND type flash memory device including a plurality of memory cells, which are serially connected to each other and selected by a word line, a first transistor connected to a first memory cell of the plurality of the memory cells, for connecting a bit line and the first memory cell, and a second transistor connected to a source terminal of a last memory cell of the plurality of the memory cells, comprising a third transistor for transferring a positive voltage to a source terminal of the second transistor according to an erase-verifying signal, upon erase-verifying operation of the memory cells; and a fourth transistor for transferring a ground voltage according to a read signal upon read operation of the memory cells.

According to still another aspect of the present invention, there is provided a NAND type flash memory device including a plurality of memory cells, which are serially connected to each other and selected by a word line, a first transistor connected to a first memory cell of the plurality of the memory cells, for connecting a bit line and the first memory cell, and a second transistor connected to a source terminal of a last memory cell of the plurality of the memory cells, comprising a third transistor for transferring a positive voltage to a source terminal of the second transistor according to an erase-verifying signal, upon erase-verifying operation of the memory cells; a resistor connected between the second transistor and the third transistor; and a fourth transistor for transferring a ground voltage according to a read signal upon read operation of the memory cells.

### BRIEF DESCRIPTION OF THE DRAWINGS

FIG. 1 is a circuit diagram for explaining an erase-verifying method of a NAND type flash memory device according to an embodiment of the present invention;

FIG. 2 shows a waveform of a bias voltage applied upon an erase-verifying operation of the NAND type flash memory device shown in FIG. 1;

FIG. 3 is a graph showing the relation between the threshold voltage of an erase cell and a source voltage Vsou;

FIG. 4 is a circuit diagram for explaining a NAND type flash memory device according to an embodiment of the present invention;

FIG. 5 shows a waveform of a bias voltage applied upon an erase-verifying operation of the NAND type flash memory device shown in FIG. 4;

FIG. 6 is a circuit diagram for explaining a NAND type flash memory device according to another embodiment of the present invention;

FIG. 7 shows a waveform of a bias voltage applied upon an erase-verifying operation of the NAND type flash memory device shown in FIG. 6; and

FIG. 8 is a graph showing the number of cells that are failed due to program disturbance when a positive voltage or a ground voltage 0V is used as the source voltage Vsou upon erase-verifying operation.

FIG. 9 and FIG. 10 show distribution of threshold voltage of flash memory device.

### DETAILED DESCRIPTION OF PREFERRED EMBODIMENTS

Now, the preferred embodiments according to the present invention will be described with reference to the accompanying drawings.

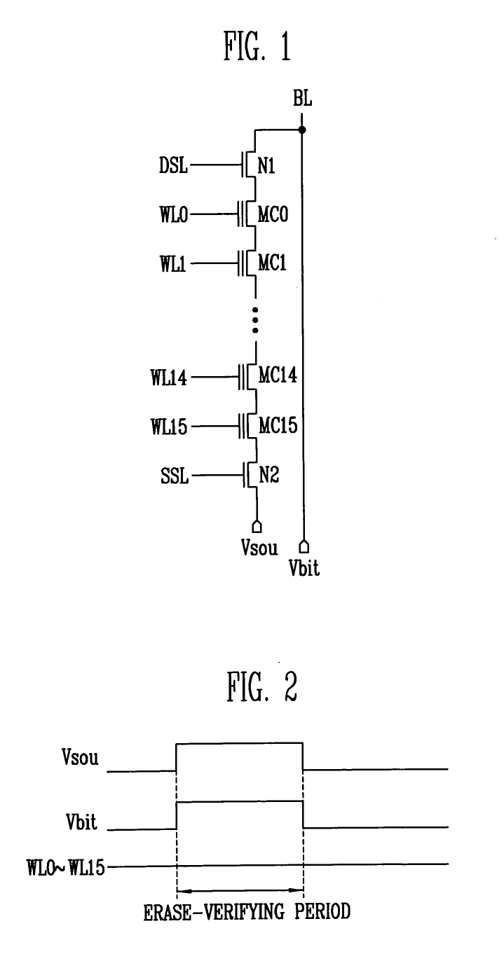

FIG. 1 is a circuit diagram for explaining an erase-verifying method of a NAND type flash memory device according to an embodiment of the present invention. FIG. 2 shows a waveform of a bias voltage applied upon an erase-verifying operation of the NAND type flash memory device shown in FIG. 1. In the present embodiment, a memory cell array wherein 16 memory cells constitute one string will be described as an example, for convenience of explanation.

Referring to FIGS. 1 and 2, in the erase-verifying method of the NAND type flash memory device according to an embodiment of the present invention, a positive voltage is applied to a source voltage Vsou applied to a source terminal of a source select transistor N2 and a bit line voltage Vbit applied to the drain terminal of a drain select transistor N1, upon erase-verifying operation. Furthermore, selected word lines WL0 to WL15 are applied with 0V. At this time, the source voltage Vsou preferably uses a voltage lower than the bit line voltage Vbit. Meanwhile, the NAND type flash memory device performs an erase-verifying operation on a block basis. Accordingly, in the above, the term “selected word line” refers to word lines selected on a block basis.

At the time of the erase-verifying operation, if the source voltage Vsou is applied as a positive voltage, electronic potential of the source of the source select transistor N2 is relatively more reduced that electronic potential within a string including the source select transistor N2. Thus, a gate bias voltage of the source select transistor N2 that is turned on is increased that much. Accordingly, a threshold voltage of an erase cell increases.

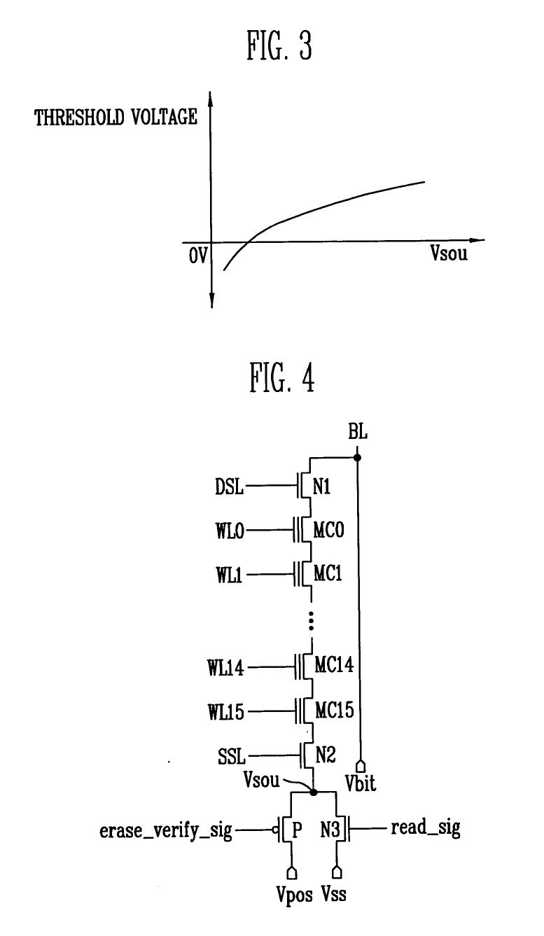

As shown in FIG. 3, the threshold voltage of the erase cell exponentially increases as the source voltage Vsou increases. Therefore, since the threshold voltage of the erase cell increases as the source voltage Vsou rises, monitoring becomes more convenient. That is, in case of an erase cell having a negative threshold voltage around 0V after the erase operation, the erase-verifying operation can be performed in an effective manner by using the erase-verifying method. Accordingly, the erase-verifying operation can be performed considering that the threshold voltage shifts due to various factors. This results in an increase in verify margin upon erase-verifying operation. In case of a cell that has failed through this erase-verifying operation, an erase cell having a stable threshold voltage can be obtained by performing an additional erase operation. Furthermore, since the stability of the overall memory cell is increased, reliability of a device can be improved.

Meanwhile, as described above, the source voltage Vsou must be lower than the bit line voltage Vbit. This is because in view of the operating characteristic of a transistor, if the source voltage Vsou is higher than the bit line voltage Vbit applied to the drain terminal, the current does not flow. Accordingly, it is preferred that the source voltage Vsou is increased by increasing the bit line voltage Vbit as possible. Upon the erase-verifying operation, the bit line voltage Vbit is generally is 0.5V to 1.5V. In a preferred embodiment of the present invention, however, it is preferred that the bit line voltage Vbit is increased to 1.5V to 3.0V in order to increase the source voltage Vsou.

Hereinafter, a NAND type flash memory device capable of implementing the erase-verifying method of the NAND type flash memory device according to embodiments of the present invention will be described.

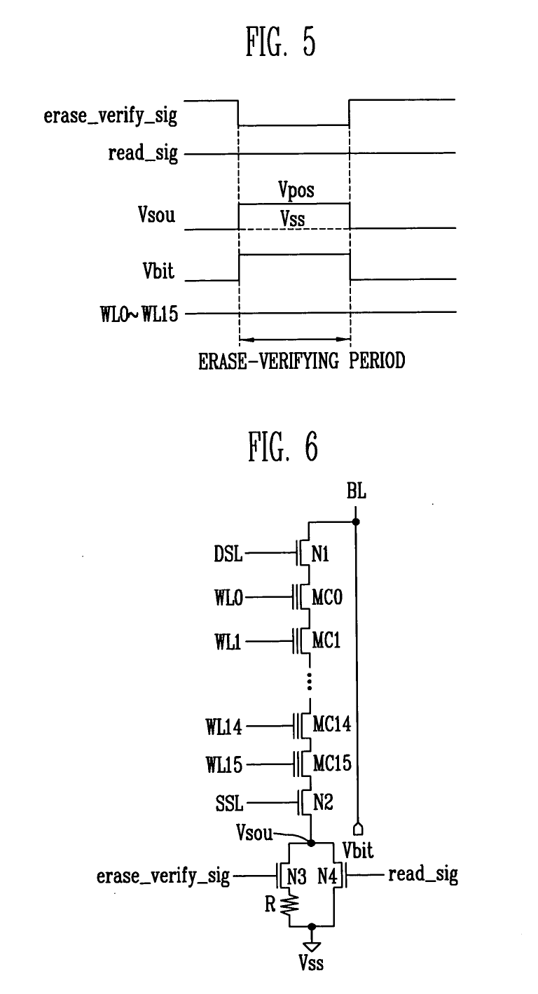

FIG. 4 is a circuit diagram for explaining a NAND type flash memory device according to an embodiment of the present invention. FIG. 5 shows a waveform of a bias voltage applied upon erase-verifying operation of the NAND type flash memory device shown in FIG. 4.

Referring to FIGS. 4 and 5, the NAND type flash memory device further includes a PMOS transistor P that is turned on by an erase-verifying signal erase_verify_sig, which is enabled (LOW level) upon erase-verifying operation, and a NMOS transistor N3 that is turned on by a read signal read_sig, which is enabled (HIGH level) upon common read operation except for the erase-verifying operation, in addition to the memory cell array of the string structure shown in FIG. 1. The PMOS transistor P is connected to a source terminal of a source select transistor N2, and it operates according to the erase-verifying signal erase_verify_sig to transfer a positive voltage Vpos to a source terminal of the source select transistor N2. The NMOS transistor N3 is connected to the source terminal of the source select transistor N2, and it operates according to the read signal read_sig to transfer a ground voltage Vss to the source terminal of the source select transistor N2.

The operational characteristic of the NAND type flash memory device constructed above is as follows.

Upon the erase-verifying operation, if the erase-verifying signal erase_verify_sig and the read signal read_sig are input as a LOW level, the PMOS transistor P is turned on and the NMOS transistor N3 is turned off. Accordingly, the positive voltage Vpos is transferred to the source terminal of the source select transistor N2 through the PMOS transistor P. That is, the source voltage Vsou becomes the positive voltage Vpos. In this state, if a positive voltage (approximately, 4.5V) is applied through a drain select line DSL and a source select line SSL, a positive bit line voltage Vbit is applied to a bit line BL, and 0V is applied to selected word lines WL0 to WL15, the erase-verifying operation is performed. As such, upon erase-verifying operation, since the positive voltage Vpos is used as the source voltage Vsou, a threshold voltage of an erase cell can be increased. Since the erase cell can be monitored with its threshold voltage being increased, erase-verifying operation margin can be increased that much.

At the time of a read operation, though not shown, if the erase-verifying signal erase_verify_sig and the read signal read_sig are input as a HIGH level, the PMOS transistor P is turned off and the NMOS transistor N3 is turned on. Accordingly, the ground voltage Vss is transferred to the source terminal of the source select transistor N2 through the NMOS transistor N3. That is, the source voltage Vsou becomes the ground voltage Vss. In this state, if a positive voltage (approximately, 4.5V) is applied through the drain select line DSL and the source select line SSL, the positive bit line voltage Vbit is applied to the bit line BL, 0.5V is applied to a selected word line (for example, WL1), and 4.5V is applied to non-selected word lines WL0 and WL2 to WL15, the read operation is performed. As such, upon common read operation, the ground voltage Vss is applied to the source terminal of the source select transistor N2.

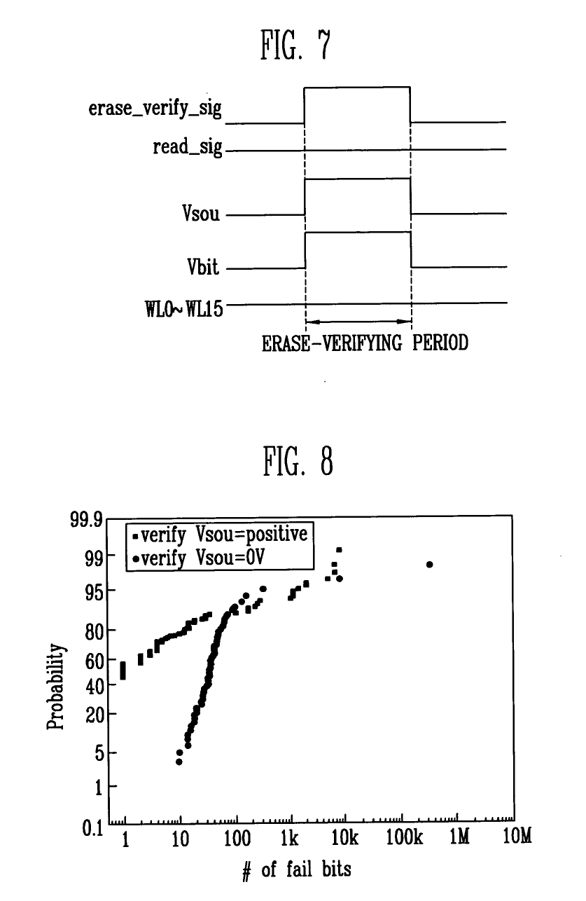

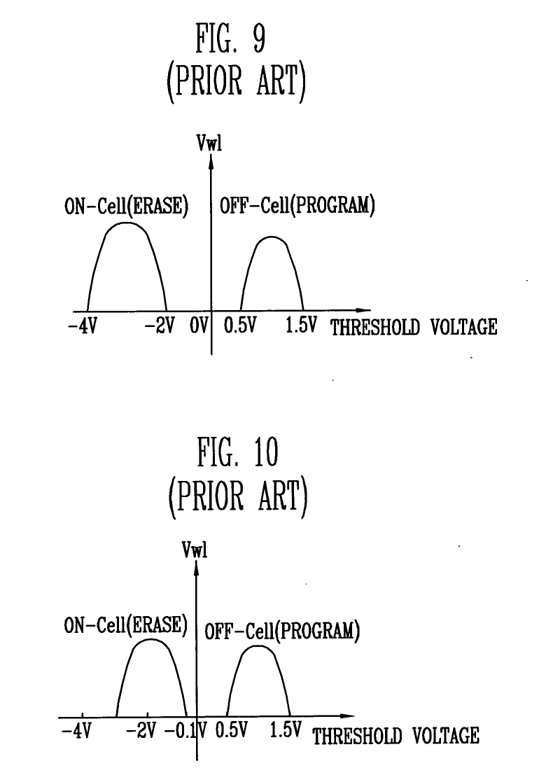

FIG. 6 is a circuit diagram for explaining a NAND type flash memory device according to another embodiment of the present invention. FIG. 7 shows a waveform of a bias voltage applied upon erase-verifying operation of the NAND type flash memory device shown in FIG. 6.

Referring to FIGS. 6 and 7, the NAND type flash memory device according to the second embodiment of the present invention further includes a NMOS transistor N3 that is turned on by an erase-verifying signal erase_verify_sig, which is enabled (HIGH level) upon erase-verifying operation, a resistor R serially connected to the NMOS transistor N3, and a NMOS transistor N4 that is turned on by a read signal read_sig, which is enable (LOW level) upon common read operation except for the erase-verifying operation, in addition to the memory cell array of the string structure shown in FIG. 1. The NMOS transistor N3 is connected between a source terminal of the source select transistor N2 and the resistor R in a serial manner, and operates according to the erase-verifying signal erase_verify_sig. The resistor R is connected between the NMOS transistor N3 and a ground voltage source. The NMOS transistor N4 is connected to the source terminal of the source select transistor N2, and operates according to the read signal read_sig to transfer the ground voltage Vss to the source terminal of the source select transistor N2.

The operational characteristic of the NAND type flash memory device constructed above is as follows.

Upon the erase-verifying operation, if the erase-verifying signal erase_verify_sig is input as a HIGH level and the read signal read_sig is input as a LOW level, the NMOS transistor N3 is turned on and the NMOS transistor N4 is turned off. Accordingly, the resistor R is applied with the ground voltage Vss. That is, if the NMOS transistor N3 is turned on, the same effect is obtained as if a predetermined positive voltage is applied to the source terminal of the source select transistor N2 by means of the resistor R. In this state, if a positive voltage (approximately, 4.5V) is applied through a drain select line DSL and a source select line SSL, a positive bit line voltage Vbit is applied to a bit line BL, and 0V is applied to selected word lines WL0 to WL15, the erase-verifying operation is carried out. As such, upon erase-verifying operation, since a positive voltage is applied to the source terminal of the source select transistor N2 using the resistor R, a threshold voltage of an erase cell can be increased. Since the erase cell having an increased threshold voltage can be monitored, erase-verifying operation margin can be increased that much.

At the time of a read operation, though not shown, if the erase-verifying signal erase_verify_sig is input as a LOW level and the read signal read_sig is input as a HIGH level, the NMOS transistor N3 is turned off and the NMOS transistor N4 is turned on. Accordingly, the ground voltage Vss is transferred to the source terminal of the source select transistor N2 through the NMOS transistor N4. That is, the source voltage Vsou becomes the ground voltage Vss. In this state, if a positive voltage (approximately, 4.5V) is applied through the drain select line DSL and the source select line SSL, the positive bit line voltage Vbit is applied to the bit line BL, 0.5V is applied to a selected word line (for example, WL1), and 4.5V is applied to non-selected word lines WL0 and WL2 to WL15, the read operation is performed. As such, upon common read operation, the ground voltage Vss is applied to the source terminal of the source select transistor N2.

Hereinafter, the characteristics of an erase cell to which the erase-verifying method of the NAND type flash memory device according to an embodiment of the present invention is applied will be described with reference to FIG. 8. FIG. 8 is a graph showing the number of cells that are failed due to program disturbance when a positive voltage or a ground voltage 0V is used as the source voltage Vsou upon an erase-verifying operation.

From FIG. 8, it can be seen that in the erase-verifying operation, in the case where the source voltage Vsou is applied as a positive voltage, the number of cells that are failed due to program disturbance is significantly reduced compared to a case where the ground voltage is applied. At this time, the term “program disturbance” means that threshold voltages of erase cells closely located are affected upon program operation. As such, the reason why the number of failed cells is small although program disturbance occurs in the case of an erase cell that has been verified through the erase-verifying method of the NAND type flash memory device according to a preferred embodiment of the present invention, is that upon erase-verifying operation, the erase-verifying operation is performed by increasing a threshold voltage of the erase cell, as described above. In other words, in the present invention, the erase-verifying operation is performed in consideration of variation in the amount of a threshold voltage of an erase cell due to subsequent program disturbance. Therefore, even when the threshold voltage of the erase cell is changed due to disturbance upon subsequent program operation, the number of cells failed due to program disturbance can be cut down.

As described above, according to the present invention, upon erase-verifying operation of a memory cell, the erase-verifying operation is performed by applying a positive voltage as a source voltage. It is thus possible to stably verify a negative threshold voltage of an erase cell, considering a variation width of the threshold voltage of the erase cell, which varies due to various factors. Through this, even when the threshold voltage of the erase cell varies due to disturbance upon subsequent program operation, the number of cells failed can be reduced. Accordingly, the present invention is advantageous in that it can improve characteristics of memory cells of NAND type flash memory devices.

Although the foregoing description has been made with reference to embodiments, it is to be understood that changes and modifications of the present invention may be made by the ordinary skilled in the art without departing from the spirit and scope of the present invention and appended claims.

What is claimed is:

1. An erase-verifying method, comprising:
providing a NAND type flash memory device including a plurality of memory cells, said plurality of memory cells being serially connected to each other and selected by a word line, a first transistor for connecting between a bit line and a first memory cell of the plurality of memory cells, and a second transistor connected between a source terminal and a last memory cell of the plurality of memory cells, and
applying 0V to the word line and a positive voltage to the bit line and the source terminal.

2. The erase-verifying method as claimed in claim 1, wherein the positive voltage applied to the source terminal is lower than the positive voltage applied to the bit line.

3. The erase-verifying method as claimed in claim 1, wherein the positive voltage applied to the bit line is 0.5V to 1.5V or 1.5V to 3.0V.

4. The erase-verifying method as claimed in claim 1, wherein a positive voltage is applied to gate terminals of the first transistor and the second transistor, respectively.

5. A NAND type flash memory device comprising:
a plurality of memory cells, said plurality of memory cells being serially connected to each other and selected by a word line;
a first transistor connected to a first memory cell of the plurality of the memory cells, for connecting a bit line and the first memory cell;
a second transistor connected to a source terminal of a last memory cell of the plurality of the memory cells;
a third transistor for transferring a positive voltage to a source terminal of the second transistor according to an erase-verifying signal, upon erase-verifying operation of the memory cells; and
a fourth transistor for transferring a ground voltage according to a read signal upon read operation of the memory cells.

6. The NAND type flash memory device as claimed in claim 5, wherein the positive voltage is lower than a bit line voltage applied to the bit line.

7. The NAND type flash memory device as claimed in claim 6, wherein the bit line voltage is 0.5V to 1.5V or 1.5V to 3.0V.

8. The NAND type flash memory device as claimed in claim 5, wherein the third transistor is a PMOS transistor.

9. The NAND type flash memory device as claimed in claim 5, wherein the fourth transistor is a NMOS transistor.

10. A NAND type flash memory device comparing:
a plurality of memory cells, said plurality of memory cells being serially connected to each other and selected by a word line;
a first transistor connected to a first memory cell of the plurality of the memory cells, for connecting a bit line and the first memory cell;
a second transistor connected to a source terminal of a last memory cell of the plurality a third transistor for transferring a positive voltage to a source terminal of the second of the memory cells;
transistor according to an erase-verifying signal, upon erase-verifying operation of the memory cells;
a resistor connected between the second transistor and the third transistor; and
a fourth transistor for transferring a ground voltage according to a read signal upon read operation of the memory cells.

11. The NAND type flash memory device as claimed in claim 10, wherein the third transistor is a NMOS transistor.

12. The NAND type flash memory device as claimed in claim 10, wherein the fourth transistor is a NMOS transistor.
